(19) United States
(12) Patent Application Publication
(10) Pub. No.: US 2025/0214181 A1
(43) Pub. Date: Jul. 3, 2025

(54) SOLDER COMPOSITION, METHOD OF PREPARING THE SAME, AND METHOD OF MANUFACTURING SEMICONDUCTOR PACKAGE USING THE SOLDER COMPOSITION

(71) Applicant: Samsung Electronics Co., Ltd., Suwon-si (KR)

(72) Inventors: Yuho Won, Suwon-si (KR); Cheonil Park, Suwon-si (KR); Soonchul Lee, Suwon-si (KR); Kunmo Chu, Suwon-si (KR); Sungjoon Joo, Suwon-si (KR); Taejong Paik, Seoul-si (KR); Dawon Lee, Seoul-si (KR); Yoonjoo Choi, Seoul-si (KR)

(21) Appl. No.: 18/932,930

(22) Filed: Oct. 31, 2024

(30) Foreign Application Priority Data
Jan. 3, 2024 (KR) 10-2024-0001066

(51) Int. Cl. B23K 35/368; B23K 101/40; H01L 23/00

(52) U.S. Cl. CPC B23K 35/368; H01L 24/11; H01L 24/81; B23K 2101/40; H01L 24/13; H01L 24/16; H01L 2224/13193; H01L 2224/13611; H01L 2224/13639; H01L 2224/13644; H01L 2224/13647; H01L 2224/13655; H01L 2224/13657; H01L 2224/16227; H01L 2924/35

(57) ABSTRACT

A solder composition includes a solder paste including a tin (Sn)-bismuth (Bi) alloy and/or a tin (Sn)-silver (Ag)-copper (Cu) alloy and a plurality of nanoparticles dispersed in the solder paste, wherein each of the nanoparticles includes a core that is spherical, the core includes a metal oxide, and the metal oxide has a density of 7 g/cm³ or more and a melting point of 2000° C. or higher.

### CROSS-REFERENCE TO RELATED APPLICATION

This U.S. nonprovisional application is based on and claims priority under 35 U.S.C. § 119 to Korean Patent Application No. 10-2024-0001066, filed on Jan. 3, 2024, in the Korean Intellectual Property Office, the disclosure of which is incorporated by reference herein in its entirety.

### BACKGROUND

Over the past few decades, discoveries in technology, materials, and manufacturing processes have led to rapid advances in computing power and wireless communications technology. Accordingly, high-performance transistors are directly implemented, and the speed of integration doubles approximately every 18 months in accordance with Moore's Law. Reducing the weight, thickness, length, and size of systems and improving power efficiency are permanent goals of the semiconductor manufacturing industry, and at this point in time when economic and physical process limits are reached, 3D integrated packaging is presented as an effective solution.

The development of 3D integrated devices began with the complementary metal-oxide semiconductor (CMOS) integrated devices presented in 1980 and has advanced through continuous research and development over the 30 years since then. Examples of 3D integration technologies include integration of logic circuits and memory circuits, sensor packaging, and heterogeneous integration of micro-electromechanical system (MEMS) and CMOS. Three-dimensional integration technology enables achievement of high reliability, low power consumption, and low manufacturing costs, as well as reduction of form factor.

### SUMMARY

The inventive concept relates to a solder composition, a method of preparing the solder composition, and a method of manufacturing a semiconductor package using the solder composition.

Embodiments of the he inventive concept provide a solder composition with improved performance and reliability.

Embodiments of the inventive concept provide a method of preparing a solder composition with improved performance and reliability.

Embodiments of the inventive concept provide a method of manufacturing a semiconductor package with improved performance and reliability.

According to an aspect of the inventive concept, there is provided a solder composition. The solder composition includes a solder paste including at least one alloy selected from a tin (Sn)-bismuth (Bi) alloy and/or a tin (Sn)-silver (Ag)-copper (Cu) alloy and a plurality of nanoparticles dispersed in the solder paste, wherein each nanoparticle in the plurality of nanoparticles include a core that is spherical, the core includes a metal oxide, and the metal oxide has a density of 7 g/cm³ or more and a melting point of 2000° C. or higher.

According to another aspect of the inventive concept, there is provided a method of preparing a solder composition. The method of preparing a solder composition includes synthesizing a nanoparticle including a core, and mixing the nanoparticle with a solder paste, wherein the synthesizing of the nanoparticle includes synthesizing the core using a hydrothermal synthesis process, and the core includes a metal oxide.

According to another aspect of the inventive concept, there is provided a method of manufacturing a semiconductor package. The method of manufacturing a semiconductor package includes preparing a solder composition including a plurality of nanoparticles, providing a substrate, and bonding a semiconductor chip on the substrate using the solder composition, wherein the plurality of nanoparticles include nanoparticles and each nanoparticle in the plurality of nanoparticles includes a core that is spherical and a metal coating layer surrounding the core, and wherein the preparing of the solder composition includes synthesizing the core using a hydrothermal synthesis process and forming the metal coating layer surrounding the core to form the nanoparticles and mixing the plurality of nanoparticles with a solder paste, wherein the solder paste includes at least one alloy selected from a tin (Sn)-bismuth (Bi) alloy and a tin (Sn)-silver (Ag)-copper (Cu) alloy, the core includes a metal oxide, and the metal oxide has a density of 7 g/cm³ or more and a melting point of 2000° C. or higher.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package manufactured using a solder composition according to embodiments;

FIG. 2 is a flowchart illustrating a method of preparing a solder composition, according to embodiments;

FIG. 3 is a flowchart of some operations of a method of preparing a solder composition, according to embodiments;

FIGS. 4A to 4D are electron microscope images of CeO₂ and CeO₂/Ag nanoparticles synthesized according to a method of preparing a solder composition according to embodiments;

FIGS. 5A and 5B are histograms illustrating the particle diameters of CeO₂ and CeO₂/Ag nanoparticles synthesized according to a method of preparing a solder composition according to embodiments;

FIGS. 6A to 6D are images illustrating enlarged transmission electron microscopy (TEM) image and energy dispersive spectroscopy (EDS) composition analysis results of CeO₂ and CeO₂/Ag nanoparticles synthesized according to a method of preparing a solder composition according to embodiments.

FIGS. 7A and 7B are X-ray diffraction (XRD) graphs of CeO₂ and CeO₂/Ag nanoparticles synthesized according to a method of preparing a solder composition according to embodiments; and

FIG. 8 is a flowchart illustrating a method of manufacturing a semiconductor package, according to embodiments.

### DETAILED DESCRIPTION OF THE EMBODIMENTS

Hereinafter, embodiments are described in detail with reference to the accompanying drawings. Items described in the singular herein may be provided in plural. Thus, the description of a single item that is provided in plural should be understood to be applicable to the remaining plurality of items unless context indicates otherwise

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” “substantially planar,” or “substantially spherical” may be exactly the same, equal, or planar or spherical, or may be the same, equal, or planar or spherical within acceptable variations that may occur, for example, due to manufacturing processes.

Throughout the specification, when a component is described as “including” a particular element or group of elements, it is to be understood that the component is formed of only the element or the group of elements, or the element or group of elements may be combined with additional elements to form the component, unless the context indicates otherwise.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

The terminology used herein is for the purpose of describing particular embodiments only and is not intended to be limiting of the invention.

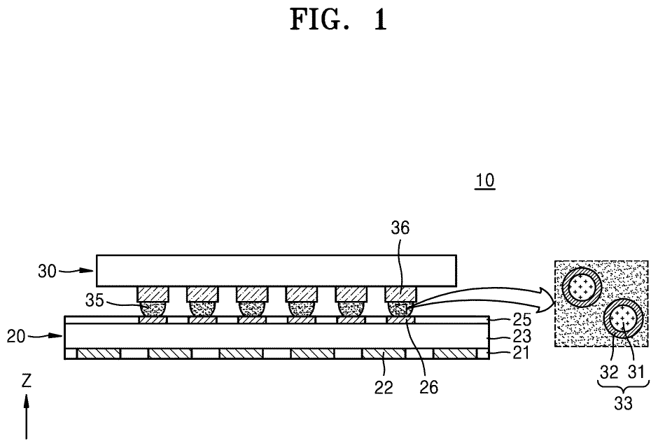

FIG. 1 is a cross-sectional view of a semiconductor package 10 manufactured using a solder composition according to embodiments.

Referring to FIG. 1, the semiconductor package 10 may include a substrate 20 and a semiconductor chip 30 bonded to the substrate 20.

In some embodiments, the substrate 20, which may be a package substrate, may include a lower insulating layer 21, an interconnection layer 23, and an upper insulating layer 25.

In some embodiments, the interconnection layer 23 may include silicon (Si). In example embodiments, the interconnection layer 23 may be formed of an intrinsic semiconductor material (e.g., a crystalline semiconductor), such as a single element, such as germanium (Ge) or Silicon (Si), or a compound semiconductor, such as silicon carbide (SiC), gallium arsenide (GaAs), indium arsenide (InAs), and indium phosphide (InP). The intrinsic semiconductor material of the interconnection layer 23 may be doped with a charge carrier dopant. In example embodiments, the interconnection layer 23 may have a silicon-on-insulator (SOI) structure. For example, the interconnection layer 23 may include a buried oxide layer (BOX) layer. The interconnection layer 23 may include a conductive region, for example, a well doped with an impurity, or may be patterned with an impurity. In addition, the interconnection layer 23 may have various device isolation structures, such as a shallow trench isolation (STI) structure.

In some embodiments, the interconnection layer 23 may include a plurality of various types of individual devices and an interlayer insulating layer. The individual devices may be various microelectronic devices, such as metal-oxide-semiconductor field effect transistors (MOSFETs), such as CMOS transistors, system large scale integration (LSI), flash memory, dynamic random-access memory (DRAM), static random-access memory (SRAM), electrically erasable programmable read-only memory (EEPROM), phase-change random-access memory (PRAM), magnetoresistive random-access memory (MRAM), or resistive random-access memory (ReRAM), image sensors, such as CMOS imaging sensors (CIS), MEMS, active elements, passive elements, etc. The individual devices may be formed in the interconnection layer 23 in a cell region CR, and the individual devices may be electrically connected to the conductive region of the interconnection layer 23. The interconnection layer 23 may further include a conductive interconnection or a conductive plug that electrically connects at least two of the individual devices or the individual devices to the conductive region of the interconnection layer 23. In addition, each of the individual devices may be electrically separated from other neighboring individual devices by insulating films.

In some embodiments, the interconnection layer 23 may include a plurality of interconnection structures for connecting the individual devices to other interconnections formed in the interconnection layer 23. The interconnection structures may include a metal interconnection pattern extending in a horizontal direction and a via plug extending in a vertical direction. The metal interconnection pattern and the via plug may include a barrier film and a conductive layer. The barrier film for interconnection may include at least one material selected from titanium (Ti), titanium nitride (TiN), tantalum (Ta), and tantalum nitride (TaN). The conductive layer may include at least one metal selected from tungsten (W), aluminum (Al), and copper (Cu). The interconnection structures may be a multi-layer structure in which two or more metal interconnection patterns and two or more via plugs are alternately stacked.

In some embodiments, the interconnection layer 23 may have lower and upper surfaces opposite to each other, the lower insulating layer 21 may be disposed on the lower surface of the interconnection layer 23, and the upper insulating layer 25 may be disposed on the upper surface of the interconnection layer 23. In this specification, lower and upper surfaces of the substrate 20 refer to surfaces perpendicular to a direction (a vertical direction, i.e., a Z direction) in which the substrate 20 is stacked. In particular, the lower surface may refer to a surface with a lower vertical level than the upper surface and the upper surface may refer to a surface with a higher vertical level than the lower surface. The lower insulating layer 21 and the upper insulating layer 25 may be protective layers to protect the interconnection layer 23 and the interconnection structure formed therein from external shock or moisture. In some embodiments, the lower insulating layer 21 and the upper insulating layer 25 may include at least one of silicon nitride, silicon oxide, and silicon oxynitride.

In some embodiments, a lower pad 22 may be disposed on the lower surface of the interconnection layer 23. A side surface of the lower pad 22 may be covered by the lower insulating layer 21. One surface of the lower pad 22 may be coplanar with the upper surface of the lower insulating layer 21 and may be exposed externally.

In some embodiments, an upper pad 26 may be disposed on the upper surface of the interconnection layer 23. A side surface of the upper pad 26 may be covered by the upper insulating layer 25. One surface of the upper pad 26 may be coplanar with the upper surface of the upper insulating layer 25 and may be exposed externally. A conductive solder 35 may be disposed on the upper pad 26 to electrically connect the substrate 20 to the semiconductor chip 30.

According to some embodiments, the lower pad 22 and the upper pad 26 may also include at least one metal selected from tungsten (W), aluminum (Al), and copper (Cu).

The semiconductor chip 30 may be disposed on the substrate 20. The conductive solder 35 may be disposed between the semiconductor chip 30 and the substrate 20.

In some embodiments, the semiconductor chip 30 may be, for example, a memory semiconductor chip. The memory semiconductor chip may be, for example, a volatile memory semiconductor chip, such as DRAM or SRAM, or a non-volatile memory semiconductor chip, such as PRAM, MRAM, FeRAM, or ReRAM.

In some embodiments, the semiconductor chip 30 may include silicon (Si). Alternatively, the semiconductor chip 30 may be formed of an intrinsic semiconductor material, such as germanium (Ge) or Silicon (Si), or a compound semiconductor, such as silicon carbide (SiC), gallium arsenide (GaAs), indium arsenide (InAs), and indium phosphide (InP). The semiconductor chip 30 may have an SOI structure. In addition, the semiconductor chip 30 may have various device isolation structures, such as an STI structure.

In some embodiments, the conductive solder 35 may be disposed between the semiconductor chip 30 and the substrate 20 to bond the semiconductor chip 30 to the substrate 20.

In some embodiments, the conductive solder 35 may include a solder material. In some embodiments, the conductive solder 35 may include one or more of tin (Sn), indium (In), bismuth (Bi), antimony (Sb), copper (Cu), silver (Ag), zinc (Zn), lead (Pb) and/or alloys thereof. For example, in some embodiments, the conductive solder 35 may include one or more of Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, etc.

In some embodiments, the conductive solder 35 may be manufactured using a solder composition in which a plurality of nanoparticles 33 are mixed with a solder paste. The nanoparticles 33 may be dispersed in a solder paste to form the solder composition.

In detail, the solder composition may include a solder paste and a plurality of nanoparticles 33 dispersed in the solder paste. The nanoparticles 33 may each include a core 31 and a metal coating layer 32 surrounding the core 31. The core 31 may include a metal oxide. In example embodiments, the core 31 may be substantially spherical or spherical.

For example, the solder paste may include at least one alloy selected from a tin (Sn)-bismuth (Bi) alloy and a tin (Sn)-silver (Ag)-copper (Cu) alloy.

For example, the metal oxide constituting the core 31 may have a density of 7 g/cm³ or more and a melting point of 2000° C. or more. For example, the metal oxide constituting the core 31 may include at least one metal oxide selected from cerium (Ce) oxide, hafnium (Hf) oxide, europium (Eu) oxide, samarium (Sm) oxide, dysprosium (Dy) oxide, terbium (Tb) oxide, erbium (Er) oxide, ytterbium (Yb) oxide, thulium (Tm) oxide, and neodymium (Nd) oxide.

For example, the diameter of the core 31 may be from 10 nm to 1000 nm. According to additional example embodiments, the diameter of the core 31 is from 100 nm to 500 nm, or from 200 nm to 300 nm. For example, a particle size distribution of the size of the core 31 of each of the nanoparticles 33 may be 20% or less. According to these embodiments, the particle sizes in are within a 20% size of one another. According to further example embodiments, the particle size distribution of the size of the core 31 of each of the nanoparticles 33 is 10% or less. According to these embodiments, the particle sizes in are within a 10% size of one another.

According to example embodiments, the plurality of nanoparticles 33 may be included in 0.1 wt % to 1 wt % of the solder composition.

According to example embodiments, for each nanoparticle of the plurality of nanoparticles, a thickness of the metal coating layer 32 may be ⅕ or less of the diameter of the core 31. The thickness of the metal coating layer will be understood to refer to the dimension of the coating perpendicular to the surface (e.g., spherical) on which it is formed. It should be appreciated that the thickness of the layer may vary and thus have several different thicknesses as respective locations. For example, for each nanoparticle of the plurality of nanoparticles, the metal coating layer 32 may include one or more metals selected from silver (Ag), nickel (Ni), gold (Au), tin (Sn), copper (Cu), and cobalt (Co).

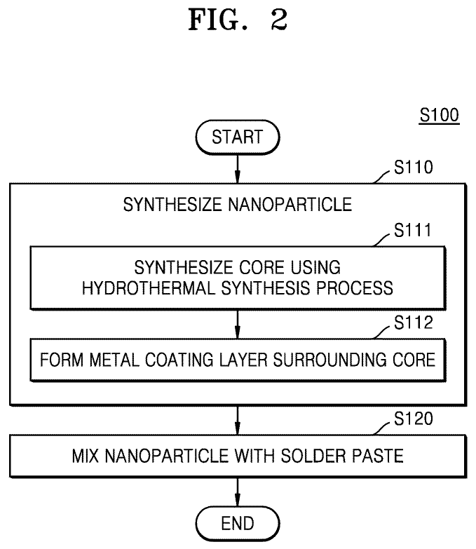

In some embodiments, the core 31 may be synthesized using a hydrothermal synthesis process. A method of preparing the solder composition including the core 31 is described in detail below with reference to FIG. 2 and the following drawings.

In some embodiments, such as shown in FIG. 1, a bump 36 may be further disposed between the semiconductor chip 30 and the conductive solder 35. The bump 36, along with the conductive solder 35, may mediate an electrical connection between the semiconductor chip 30 and the substrate 20. The bump 36, together with the conductive solder 35, may form a conductive post. The bump 36 may include at least one metal selected from tungsten (W), aluminum (Al), and copper (Cu). Bump 36 in embodiments of the present invention may be in the form of a pillar or pad, which is separately provided from conductive solder 35.

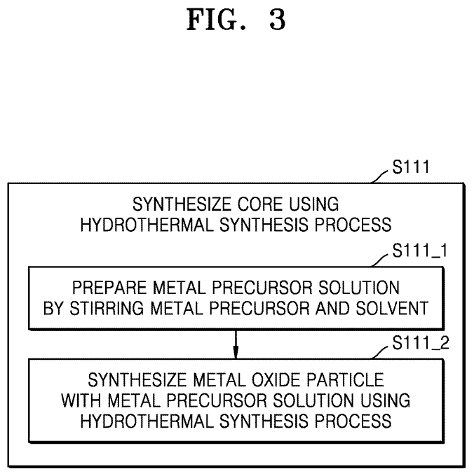

FIG. 2 is a flowchart illustrating a method (S100) of preparing a solder composition, according to embodiments. FIG. 3 is a flowchart of some operations of the method (S100) of preparing a solder composition, according to embodiments.

Referring to FIG. 2, an operation (S110) of synthesizing the nanoparticles 33 (see FIG. 1) is performed. As described above, the nanoparticle 33 includes the core 31 (see FIG. 1) and the metal coating layer 32 (see FIG. 1) surrounding the core 31.

First, as illustrated in FIG. 2, an operation (S111) of synthesizing the core 31 using a hydrothermal synthesis process is performed.

In detail, referring to FIG. 3, the operation (S111) of synthesizing the core 31 using a hydrothermal synthesis process includes an operation (S111_1) of preparing a metal precursor solution by stirring a metal precursor and a solvent and an operation (S111_2) of synthesizing metal oxide particles with the metal precursor solution using a hydrothermal synthesis process.

First, the operation (S111_1) of preparing the metal precursor solution by stirring a metal precursor and a solvent is performed. For example, the metal precursor solution is prepared by stirring a metal precursor, a ligand, and a solvent.

In example embodiments, the metal precursor may include, for example, at least one selected from a cerium (Ce) precursor, a hafnium (Hf) precursor, a europium (Eu) precursor, a samarium (Sm) precursor, a dysprosium (Dy) precursor, a terbium (Tb) precursor, an erbium (Er) precursor, an ytterbium (Yb) precursor, a thulium (Tm) precursor, and a neodymium (Nd) precursor.

Next, the operation (S111_2) of synthesizing metal oxide particles is performed with the metal precursor solution, which is prepared in the operation (S111_1) of preparing the metal precursor solution, using a hydrothermal synthesis process.

For example, the hydrothermal synthesis process may be carried out at a temperature of 100° C. to 300° C. For example, the hydrothermal synthesis process may be carried out for 1 hour to 20 hours. By way of non-limiting example embodiment, the hydrothermal synthesis process may be carried out at a temperature of 130° C. to 180° C. According to example embodiments, the hydrothermal synthesis process may be carried out for 16 hours to 20 hours. Alternatively, the hydrothermal synthesis process may be carried out for 1 hour to 5 hours.

The core 31 may be manufactured by synthesizing the metal oxide particles.

In some embodiments, the diameter of the core 31 synthesized in the operation (S111) of synthesizing the core using a hydrothermal synthesis process according to the inventive concept may be 10 nm to 1000 nm. In some embodiments, the size of the core 31 synthesized in the operation (S111) of synthesizing the core using a hydrothermal synthesis process is relatively uniform. For example, the particle size distribution of the size of the core 31 synthesized in the operation (S111) of synthesizing the core using a hydrothermal synthesis process may be 20% or less. For example, the particle size distribution of the size of the core 31 synthesized in the operation (S111) of synthesizing the core using a hydrothermal synthesis process may be 10% or less.

Referring back to FIG. 2, an operation (S112) of forming the metal coating layer 32 surrounding the core 31 may be performed. In detail, after forming a metal seed layer on the core 31, a process of coating the core 31 with metal may be performed.

The metal coating layer 32 may include, for example, one or more metals selected from silver (Ag), nickel (Ni), gold (Au), tin (Sn), copper (Cu), and cobalt (Co).

In some embodiments, a thickness of the metal coating layer 32 may be ⅕ or less of the diameter of the core 31. For example, when the diameter of the core 31 is 10 nm, the thickness of the metal coating layer 32 may be 2 nm or less. For example, when the diameter of the core 31 is 1000 nm, the thickness of the metal coating layer 32 may be 200 nm or less.

Through the operation (S110) of synthesizing nanoparticles according to embodiments, the nanoparticles 33 including the core 31 and the metal coating layer 32 surrounding or coating the core 31 is synthesized.

Referring back to FIG. 2, an operation (S120) of mixing the nanoparticles 33 with the solder paste is performed.

In some embodiments, the solder paste may include one or more metals selected from a tin (Sn)-bismuth (Bi) alloy and a tin (Sn)-silver (Ag)-copper (Cu) alloy.

In some embodiments, in order to mix the nanoparticles 33 with the solder paste, a mixture of the nanoparticles 33 and the solder paste may be stirred. In some embodiments, the nanoparticles 33 may be mixed with the solder paste to be included in an amount of 0.1 wt % to 1 wt % of the solder composition.

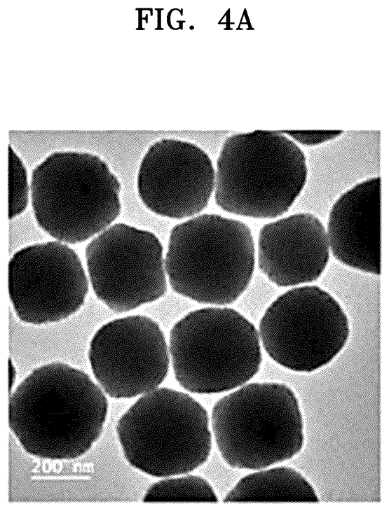

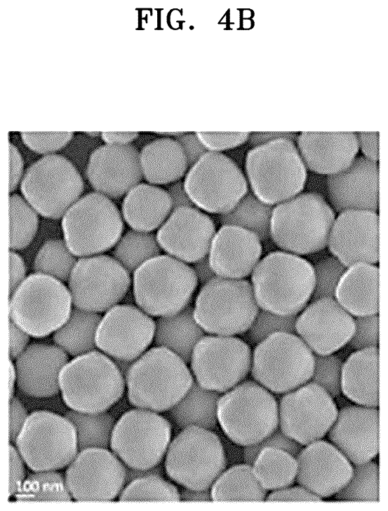

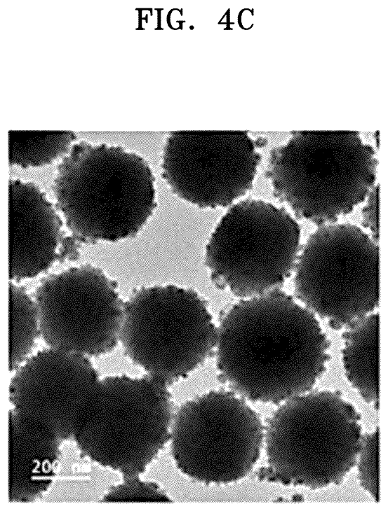

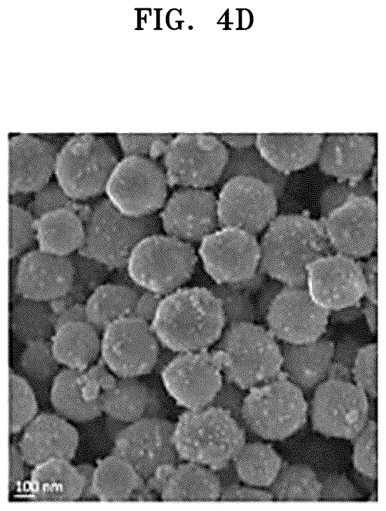

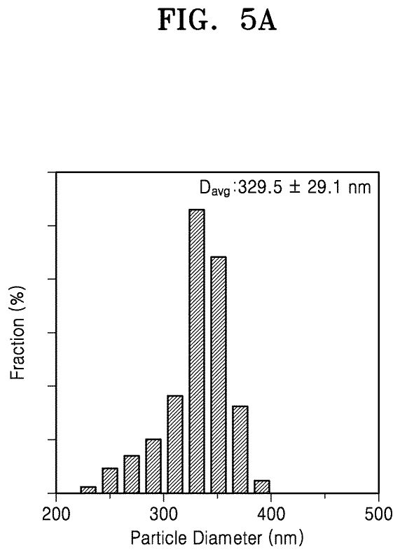

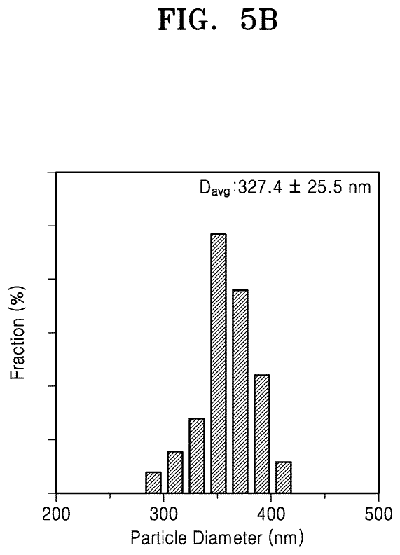

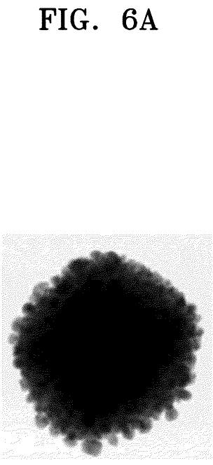

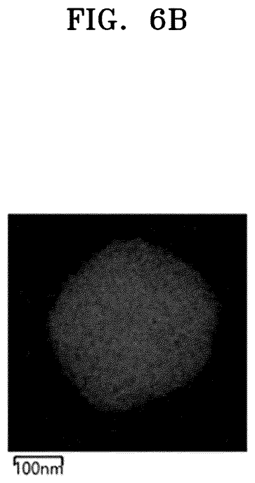

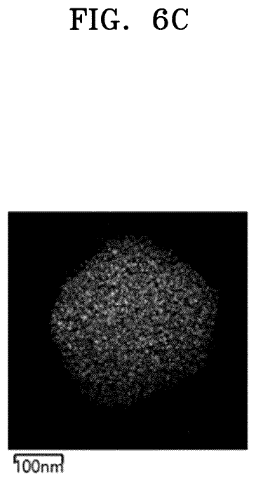

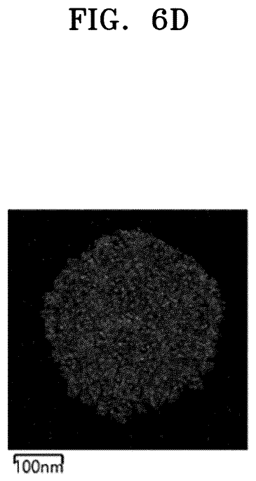

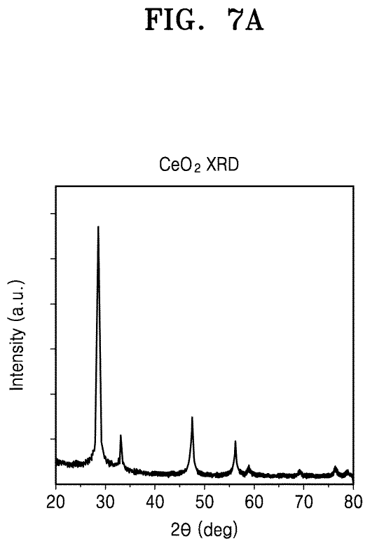

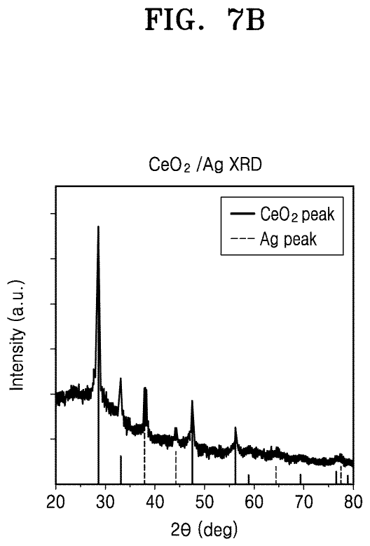

FIGS. 4A to 4D are electron microscope images of CeO₂ and CeO₂/Ag nanoparticles synthesized according to a method of preparing a solder composition according to example embodiments. FIGS. 5A and 5B are histograms illustrating the diameters of CeO₂ and CeO₂/Ag nanoparticles synthesized according to a method of preparing a solder composition according to embodiments. FIGS. 6A to 6D are images illustrating enlarged transmission electron microscopy (TEM) image and energy dispersive spectroscopy (EDS) composition analysis results of CeO₂ and CeO₂/Ag nanoparticles synthesized according to a method of preparing a solder composition according to embodiments. FIGS. 7A and 7B are X-ray diffraction (XRD) graphs of CeO₂ and CeO₂/Ag nanoparticles synthesized according to a method of preparing a solder composition according to embodiments.

The configuration and effects of the inventive concept are described in more detail through examples and comparative examples herein, but these examples are only intended to provide a clearer understanding of the inventive concept and are not intended to limit the scope of the inventive concept.

In some embodiments, CeO₂ nanoparticles are synthesized as set forth in Example 1. In some embodiments, CeO₂/Ag nanoparticles are synthesized as set forth in Example 2.

Example 1: Cerium(III) nitrate hexahydrate (Ce(NO₃)₃·6H₂O) and polyvinylpyroliodine (PVP) 1300K were hydrothermally synthesized in a 1:3 ratio at 160° C. for 18 hours.

Example 2: 1 g of CeO₂ nanoparticles of Example 1 was dispersed in 250 ml of deionized (DI) water, and then 50 ml of NaOH 0.1 M was added to adjust the pH to 12. After forming an Ag seed layer on the surface of CeO₂ nanoparticles using silver nitrate (AgNO₃), Ag NO₃ was additionally injected to coat the surface with Ag.

Through this, CeO₂ nanoparticles and CeO₂/Ag nanoparticles, as illustrated in FIGS. 4A to 4D, may be synthesized.

In detail, FIG. 4A is a TEM image of CeO₂ nanoparticles of Example 1. FIG. 4B is an SEM image of CeO₂ nanoparticles of Example 1. FIG. 4C is a TEM image of CeO₂/Ag nanoparticles of Example 2. FIG. 4D is an SEM image of CeO₂/Ag nanoparticles of Example 2.

As illustrated in FIGS. 4A to 4D, it can be seen that nanoparticles with a diameter of 500 nm or less are synthesized by synthesizing the CeO₂ nanoparticles and CeO₂/Ag nanoparticles of Examples 1 and 2 using a hydrothermal synthesis process according to embodiments.

Next, referring to FIGS. 5A and 5B, the distribution of sizes of the CeO₂ nanoparticles and CeO₂/Ag nanoparticles of Examples 1 and 2 synthesized using a hydrothermal synthesis process according to embodiments may be identified. In detail, FIG. 5A is a histogram illustrating the distribution of diameters of CeO₂ nanoparticles of Example 1. FIG. 5B is a histogram illustrating the distribution of diameters of CeO₂/Ag nanoparticles of Example 2.

As illustrated in FIG. 5A, it can be seen that the average diameter D_{avg} of the CeO₂ nanoparticles of Example 1 is about 329.5 nm, with a distribution of about 10%. As illustrated in FIG. 5B, it can be seen that the average diameter D_{avg} of the CeO₂/Ag nanoparticles of Example 2 is about 327.4 nm, with a distribution of about 10%.

By synthesizing the core using a hydrothermal synthesis process according to the method (S100) of preparing a solder composition, according to embodiments, nanoparticles having a particle size distribution of 20% or less may be manufactured. In example embodiments, by synthesizing the core using a hydrothermal synthesis process according to the method (S100) of preparing a solder composition, nanoparticles having a particle size distribution of 10% or less may be manufactured. Accordingly, nanoparticles with improved particle size distribution may be manufactured.

Referring to FIGS. 6A to 6D, it may be seen that the CeO₂/Ag nanoparticles of Example 2 were synthesized. In detail, FIG. 6A is an enlarged TEM image of the CeO₂/Ag nanoparticles in FIG. 4C. FIGS. 6B to 6D are images showing result of EDS composition analysis using the image of FIG. 6A, each marked with cerium (Ce), oxygen (O), and silver (Ag).

Referring to FIGS. 7A and 7B, it can be seen that the CeO₂ nanoparticles of Example 1 and the CeO₂/Ag nanoparticles of Example 2 were synthesized. FIGS. 7A and 7B are XRD analysis graphs of CeO₂ nanoparticles of Example 1 and CeO₂/Ag nanoparticles of Example 2, respectively.

As illustrated in FIG. 7A, CeO₂ peaks may be identified by XRD analysis of the CeO₂ nanoparticles of Example 1. As illustrated in FIG. 7B, CeO₂ peaks and Ag peaks may be identified, respectively, by XRD analysis of the CeO₂/Ag nanoparticles of Example 2.

The nanoparticles of Examples 1 and 2 were mixed with a solder paste, and thermal cycle (TC) evaluation was performed compared to Comparative Example 1 to Comparative Example 3. (See Table 1 below)

Comparative Examples 1 to 3 are a case in which nanoparticles were not mixed with the solder paste (Comparative Example 1) and cases in which ZnSe nanoparticles and In₂O₃ nanoparticles were respectively mixed with the solder pastes (Comparative Example 2 and Comparative Example 3). In Comparative Example 2 and Comparative Example 3, nanoparticles without a metal coating were mixed with solder paste.

TABLE 1

| | | | | Shear strength | | |
|---|---|---|---|---|---|---|
| | | | Melting | (Mpa) | | |
| | | Density | point | 0 | 500 | Reduction |
| | | (g/cm³) | (° C.) | cycle | cycle | rate |
| Comparative | w/o NP | | | 74.6 | 69.6 | −7% |
| Example 1 | | | | | | |
| Comparative | ZnSe | 5.27 | 1525 | 74.7 | 66 | −12% |
| Example 2 | | | | | | |
| Comparative | In₂O₃ | 7.18 | 1910 | 75.1 | 67.7 | −10% |
| Example 3 | | | | | | |
| Example 1 | CeO₂ | 7.22 | 2400 | 71.8 | 68.6 | −5% |
| Example 2 | CeO₂/Ag | | | 70.3 | 68.1 | −3% |

Referring to Table 1, in the case of Comparative Example 1 in which no nanoparticles were mixed, the shear strength decreased by about −7% from 74.6 MPa to 69.6 MPa after performing 500 cycles.

In Comparative Example 2, ZnSe nanoparticles with a density of 5.27 g/cm³ and a melting point of 1525° C. were mixed with the solder paste, and as a result of performing 500 cycles, the shear strength decreased by about −12% from 74.7 MPa to 66 MPa.

In Comparative Example 3, In₂O₃ nanoparticles with a density of 7.18 g/cm³ and a melting point of 1910° C. were mixed with the solder paste, and as a result of performing 500 cycles, the shear strength decreased by about −10% from 75.1 MPa to 67.7 MPa.

In Example 1, CeO₂ nanoparticles having a density of 7.22 g/cm³ and a melting point of 2400° C. were mixed with the solder paste, and as a result of performing 500 cycles, the shear strength decreased by about −5% from 71.8 MPa to 68.6 MPa.

In Example 2, CeO₂/Ag nanoparticles including an Ag-coated CeO₂ core and having a density of 7.22 g/cm³ and a melting point of 2400° C. were mixed with the solder paste, and as a result of performing 500 cycles, the shear strength decreased by about −3% from 70.3 MPa to 68.1 MPa.

As a result of the TC test of Example 1, Example 2, and Comparative Examples 1 to 3 as described above, it can be seen that, in the case of Example 1 in which the CeO₂ nanoparticles were mixed, the reduction rate of the shear strength was reduced, compared to the case of Comparative Example 1. In addition, it can be seen that, in the case of Example 2 in which CeO₂/Ag nanoparticles including an Ag-coated CeO₂ core were mixed, the reduction rate of shear strength was further reduced.

It can be seen that, the ZnSe nanoparticles of Comparative Example 2 had a density less than 7 g/cm³ and a melting point less than 2000° C., and that the reduction rate of shear strength of Comparative Example 2 increased compared to the case of Comparative Example 1 in which nanoparticles were not mixed and the cases of Example 1 and Example 2 in which CeO₂ nanoparticles and CeO₂/Ag nanoparticles were mixed, respectively.

Similarly, the In₂O₃ nanoparticles of Comparative Example 3 had a melting point of 2000° C. or less, and it can be seen that the reduction rate of shear strength of Comparative Example 3 increased, compared to the case of Comparative Example 1 in which nanoparticles were not mixed and Example 1 and Example 2 in which CeO₂ nanoparticles and CeO₂/Ag nanoparticles were mixed, respectively.

It can be seen that, in the case of Comparative Example 2 and Comparative Example 3, there is no effect of improving the reliability of the solder composition.

As the solder composition according to Examples herein includes a metal oxide having high density (7 g/cm³ or more) and high melting point (2000° C. or higher), a phenomenon in which a plurality of nanoparticles are phase-separated from the solder composition may be improved. Accordingly, the shear strength properties of the solder composition may be improved. Accordingly, according to embodiments, a solder composition having improved performance and reliability may be provided.

Because the solder composition according to embodiments further includes the metal coating layer surrounding the core, the solder composition including nanoparticles having improved wetting characteristics with the solder paste are provided. Accordingly, the shear strength properties of the solder composition are improved. Thus, according to example embodiments, the solder composition having improved performance and reliability is provided.

Because the method of preparing a solder composition according to embodiments synthesizes nanoparticles including a metal oxide having high density (7 g/cm³ or more) and high melting point (2000° C. or higher), the phenomenon in which the nano particles are phase-separated from the solder composition is improved. Accordingly, the shear strength properties of the solder composition are improved. According to embodiments, the method of preparing a solder composition having improved performance and reliability may be provided.

Because the solder composition according to embodiments further includes the metal coating layer surrounding the core, the method of preparing a solder composition that produces nanoparticles having improved wetting characteristics with the solder paste may be provided. Accordingly, the shear strength properties of the solder composition may be improved. That is, according to embodiments, the method of preparing a solder composition having improved performance and reliability may be provided.

According to example embodiments, metal oxides that may be used as cores of nanoparticles with high density (7 g/cm³ or more) and high melting point (2000° C. or higher) are shown in Table 2 below.

TABLE 2

| | Density | Melting point |
|---|---|---|
| | (g/cm³) | (° C.) |
| CeO₂ | 7.22 | 2400 |
| HfO₂ | 9.68 | 2758 |
| Eu₂O₃ | 7.4 | 2350 |
| Sm₂O₃ | 8.35 | 2335 |
| Dy₂O₃ | 7.8 | 2408 |
| Tb₂O₃ | 7.91 | 2410 |
| Er₂O₃ | 8.64 | 2344 |
| Yb₂O₃ | 9.17 | 2355 |
| Tm₂O₃ | 8.6 | 2341 |
| Nd₂O₃ | 7.24 | 2233 |

According to example embodiments, the core of the nanoparticles of the solder composition according to embodiments include one or more metal oxides selected from cerium (Ce) oxide, hafnium (Hf) oxide, europium (Eu) oxide, samarium (Sm) oxide, dysprosium (Dy) oxide, terbium (Tb) oxide, erbium (Er) oxide, ytterbium (Yb) oxide, thulium (Tm) oxide, and neodymium (Nd) oxide.

The core of the nanoparticles synthesized by the method of preparing a solder composition according to embodiments may include one or more selected from cerium (Ce) oxide, hafnium (Hf) oxide, europium (Eu) oxide, samarium (Sm) oxide, dysprosium (Dy) oxide, terbium (Tb) oxide, erbium (Er) oxide, ytterbium (Yb) oxide, thulium (Tm) oxide, and neodymium (Nd) oxide.

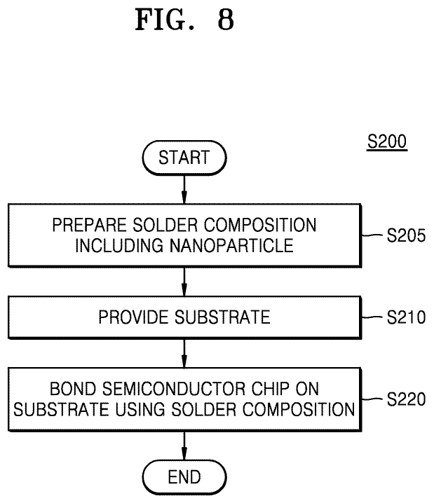

FIG. 8 is a flowchart illustrating a method (S200) of manufacturing a semiconductor package, according to embodiments.

Referring to FIG. 8, an operation (S205) of preparing a solder composition including nanoparticles is performed. The operation (S205) of preparing a solder composition including nanoparticles in the method (S200) of manufacturing a semiconductor package may include for example, the method (S100) of preparing a solder composition described above with reference to FIGS. 2 and 3.

In embodiments in which operation (S205) of preparing a solder composition is the operation (S100) of preparing a solder composition including nanoparticles, the method may include the operation (S111) of synthesizing a core using a hydrothermal synthesis process, the operation (S112) of forming a metal coating layer surrounding the core, and the operation (S120) of mixing the nanoparticles with the solder paste. The operation (S111) of synthesizing the core 31 using a hydrothermal synthesis process may include, for example, the operation (S111_1) of preparing a metal precursor solution by stirring a metal precursor and a solvent and the operation (S111_2) of synthesizing metal oxide particles using with the metal precursor solution a hydrothermal synthesis process.

Subsequently, an operation (S210) of providing a substrate may be performed. For example, the substrate 20 described above with reference to FIG. 1 may be provided.

Next, an operation (S220) of bonding a semiconductor chip to the substrate using a solder composition may be performed. For example, the semiconductor chip 30 described above with reference to FIG. 1 may be bonded to the substrate 20.

According to example embodiments, a solder composition prepared through an operation (S205). Operation (S205) may include for example, an operation such as that to prepare (S100) of preparing a solder composition including a plurality of nanoparticles may be applied below the semiconductor chip 30, which may be disposed on the substrate 20, and thereafter, the substrate 20 may be bonded to the semiconductor chip 30 by applying heat and/or pressure thereto.

For example, the bump 36 (see FIG. 1) coated with the solder composition prepared through the operation (S100) of preparing a solder composition including a plurality of nanoparticles may be attached below the semiconductor chip 30, the semiconductor chip 30 with bump attached below may be disposed on the substrate 20, and the substrate 20 may then be bonded to the semiconductor chip 30 by applying heat and/or pressure.

The semiconductor package 10 described above with reference to FIG. 1 may be manufactured by the method (S200) of manufacturing a semiconductor package described above with reference to FIG. 12.

According to embodiments, the method (S200) of manufacturing a semiconductor package using a solder composition including a plurality of nanoparticles may be provided. According to example embodiments, the method (S200) of manufacturing a semiconductor package having improved performance and reliability may be provided.

While the inventive concept has been particularly shown and described with reference to embodiments thereof, it will be understood that various changes in form and details may be made therein without departing from the spirit and scope of the following claims.

What is claimed is:

1. A solder composition comprising:
a solder paste comprising at least one alloy selected from the group consisting of a tin (Sn)-bismuth (Bi) alloy and a tin (Sn)-silver (Ag)-copper (Cu) alloy; and
a plurality of nanoparticles dispersed in the solder paste,
wherein each nanoparticle in the plurality of nanoparticles includes a core that is spherical,
wherein the core includes a metal oxide, and
wherein the metal oxide has a density of 7 g/cm³ or more and a melting point of 2000° C. or higher.

2. The solder composition of claim 1, wherein the core is synthesized using a hydrothermal synthesis process.

3. The solder composition of claim 1, wherein the core includes at least one metal oxide selected from the group consisting of cerium (Ce) oxide, hafnium (Hf) oxide, europium (Eu) oxide, samarium (Sm) oxide, dysprosium (Dy) oxide, terbium (Tb) oxide, erbium (Er) oxide, ytterbium (Yb) oxide, thulium (Tm) oxide, and neodymium (Nd) oxide.

4. The solder composition of claim 1, wherein each core has a diameter from 10 nm to 1000 nm.

5. The solder composition of claim 4, wherein a particle size distribution of the diameter of the core is 20% or less, such that the core sizes are within 20% size of one another.

6. The solder composition of claim 1, wherein the plurality of nanoparticles is included in an amount of 0.1 wt % to 1 wt % of the solder composition.

7. The solder composition of claim 1, wherein each nanoparticle in the plurality of nanoparticles further includes a metal coating layer surrounding the core.

8. The solder composition of claim 7, wherein for each nanoparticle of the plurality of nanoparticles, a thickness of the metal coating layer is less than ⅕ of a diameter of the core.

9. The solder composition of claim 7, wherein for each nanoparticle of the plurality of nanoparticles, the metal coating layer includes one or more metals selected from the group consisting of silver (Ag), nickel (Ni), gold (Au), tin (Sn), copper (Cu), and cobalt (Co).

10. A method of preparing a solder composition, the method comprising:
synthesizing a nanoparticle including a core; and
mixing the nanoparticle with a solder paste,
wherein the synthesizing of the nanoparticle includes synthesizing the core using a hydrothermal synthesis process, and wherein the core includes a metal oxide.

11. The method of claim 10, wherein
the synthesizing of the core comprises:
preparing a metal precursor solution by stirring a metal precursor and a solvent; and
synthesizing metal oxide particles with the metal precursor solution using the hydrothermal synthesis process,
wherein the hydrothermal synthesis process is carried out for about 1 hour to about 20 hours at a temperature of 100° C. to 300° C.

12. The method of claim 10, wherein the metal oxide has a density of 7 g/cm³ or more and a melting point of 2000° C. or higher.

13. The method of claim 10, wherein the core includes at least one metal oxide selected from the group consisting of cerium (Ce) oxide, hafnium (Hf) oxide, europium (Eu) oxide, samarium (Sm) oxide, dysprosium (Dy) oxide, terbium (Tb) oxide, erbium (Er) oxide, ytterbium (Yb) oxide, thulium (Tm) oxide, and neodymium (Nd) oxide.

14. The method of claim 10, wherein the synthesizing of the nanoparticle further comprises forming a metal coating layer surrounding the core.

15. The method of claim 14, wherein the metal coating layer comprises one or more metals selected from the group consisting of silver (Ag), nickel (Ni), gold (Au), tin (Sn), copper (Cu), and cobalt (Co).

16. The method of claim 10, wherein the solder paste comprises at least one alloy selected from the group consisting of a tin (Sn)-bismuth (Bi) alloy and a tin (Sn)-silver (Ag)-copper (Cu) alloy.

17. A method of manufacturing a semiconductor package, the method comprising:
preparing a solder composition including a plurality of nanoparticles;
providing a substrate; and
bonding a semiconductor chip on the substrate using the solder composition,
wherein the plurality of nanoparticles comprise nanoparticles, and wherein each nanoparticle in the plurality of nanoparticles includes a core that is spherical and a metal coating layer surrounding the core, and
wherein the preparing of the solder composition comprises:
synthesizing the core using a hydrothermal synthesis process and forming the metal coating layer surrounding the core, to form the nanoparticles; and
mixing the plurality of nanoparticles with a solder paste,
wherein the solder paste comprises at least one alloy selected from the group consisting of a tin (Sn)-bismuth (Bi) alloy and a tin (Sn)-silver (Ag)-copper (Cu) alloy,
wherein the core includes a metal oxide, and
wherein the metal oxide has a density of 7 g/cm³ or more and a melting point of 2000° C. or higher.

18. The method of claim 17, wherein
the synthesizing of the core comprises:
preparing a metal precursor solution by stirring a metal precursor and a solvent; and
synthesizing metal oxide particles with the metal precursor solution using the hydrothermal synthesis process,
wherein the hydrothermal synthesis process is carried out for about 1 hour to about 20 hours at a temperature of 100° C. to 300° C.

19. The method of claim 17, wherein the core includes at least one metal oxide selected from the group consisting of cerium (Ce) oxide, hafnium (Hf) oxide, europium (Eu) oxide, samarium (Sm) oxide, dysprosium (Dy) oxide, terbium (Tb) oxide, erbium (Er) oxide, ytterbium (Yb) oxide, thulium (Tm) oxide, and neodymium (Nd) oxide.

20. The method of claim 17, wherein the metal coating layer comprises one or more metals selected from the group consisting of silver (Ag), nickel (Ni), gold (Au), tin (Sn), copper (Cu), and cobalt (Co).
